(19) United States
(12) Patent Application Publication
(10) Pub. No.: US 2026/0033186 A1
(43) Pub. Date: Jan. 29, 2026

(54) DISPLAY PANEL AND PREPARATION METHOD THEREFOR, AND DISPLAY DEVICE

(71) Applicant: Hefei Visionox Technology Co., Ltd., Hefei (CN)

(72) Inventors: Wenyu ZENG, Hefei (CN); Wenlong WANG, Hefei (CN); Shundong BAO, Hefei (CN); Jingping ZHANG, Hefei (CN)

(73) Assignee: Hefei Visionox Technology Co., Ltd., Hefei (CN)

(21) Appl. No.: 19/275,892

(22) Filed: Jul. 21, 2025

(30) Foreign Application Priority Data
Jul. 29, 2024 (CN) 202411031585.3

(51) Int. Cl. H10K 59/131; H10K 59/12; H10K 59/122

(52) U.S. Cl. CPC H10K 59/131; H10K 59/1201; H10K 59/122

(57) ABSTRACT

The present application provides a display panel having an active area and a non-active area at least partially surrounding the active area. The display panel includes: a substrate; an array layer located on one side of the substrate, the array layer including a first conductive layer, the first conductive layer including a first metal trace, the first metal trace being located at least in the non-active area; and a protective layer located on a side of the first conductive layer facing away from the substrate and in the non-active area, the protective layer covering at least part of the first metal trace located in the non-active area.

### CROSS-REFERENCE TO RELATED APPLICATIONS

The present application claims priority to Chinese Patent Application No. 202411031585.3, entitled “DISPLAY PANEL AND PREPARATION METHOD THEREFOR, AND DISPLAY DEVICE” and filed on Jul. 29, 2024, which is incorporated herein by reference in its entirety.

### FIELD

The present application relates to the field of display, and in particular to a display panel and a preparation method therefor, and a display device.

### BACKGROUND

With the development of display technology, display panels with organic light-emitting diodes (OLED) have the advantages of self-luminescence, low drive voltage, high luminous efficiency, short response time, high clarity and contrast, etc., and are one of the commonly used display screens for electronic devices such as mobile phones, tablet computers, smart televisions, and smart wearable devices.

### SUMMARY

In order to solve the above problem, embodiments of the present application provide a display panel and a preparation method therefor, and a display device.

In a first aspect, an embodiment of the present application provides a display panel, having an active area and a non-active area at least partially surrounding the active area. The display panel includes: a substrate; an array layer located on one side of the substrate, the array layer including a first conductive layer, the first conductive layer including a first metal trace, the first metal trace being located at least in the non-active area; and a protective layer located on a side of the first conductive layer facing away from the substrate and in the non-active area, the protective layer covering at least part of the first metal trace located in the non-active area.

With reference to the first aspect, a cladding of the protective layer on the first metal trace has a thickness greater than or equal to 1000 Å and less than or equal to 5000 Å. In one embodiment, a material of the protective layer includes at least one of an inorganic material and an organic material. In one embodiment, the first metal trace extends from the non-active area to the active area. In one embodiment, in a direction perpendicular to the substrate, the first metal trace includes a first metal layer, a second metal layer and a third metal layer sequentially stacked in a direction away from the substrate, and the protective layer at least covers a side surface of the second metal layer. In one embodiment, the protective layer covers a side surface of the first metal layer, a side surface of the second metal layer and a side surface of the third metal layer. In one embodiment, the protective layer extends from a side surface of the first metal layer to a surface of the third metal layer away from the substrate, and covers at least part of the surface of the third metal layer away from the substrate.

With reference to the first aspect, the non-active area includes a dam area and a groove area, the groove area being located on a side of the dam area away from the active area; and the array layer further includes a planarization layer located on the side of the first conductive layer facing away from the substrate, the planarization layer having a groove in the groove area, the groove exposing part of the first metal trace, and the protective layer at least partially covering the first metal trace exposed at the groove. In one embodiment, the protective layer at least covers a side surface of the first metal trace exposed at the groove. In one embodiment, the non-active area further includes a bendable area located on a side of the groove area away from the dam area.

With reference to the first aspect, the protective layer at least partially covers the first metal trace and extends in a direction away from the first metal trace until covering the groove. In one embodiment, the protective layer is provided with first openings, an orthographic projection of the plurality of first openings on the substrate being misaligned with an orthographic projection of the first metal trace on the substrate.

With reference to the first aspect, the protective layer covers at least part of the first metal trace in the dam area. In one embodiment, in at least part of the dam area, the protective layer at least partially covers the first metal trace. In one embodiment, the dam area includes at least two dams, and the protective layer at least partially covers the first metal trace located between adjacent dams. In one embodiment, the protective layer at least partially covers the first metal trace and extends in a direction away from the first metal trace until covering at least part of the dam area. In one embodiment, the protective layer is provided with first openings, an orthographic projection of the plurality of first openings on the substrate being misaligned with an orthographic projection of the first metal trace on the substrate. In one embodiment, the protective layer extends from the groove area to the dam area and covers at least part of the first metal trace in the dam area.

With reference to the first aspect, the non-active area further includes a first non-active area, the first non-active area being located between the dam area and the active area, and the protective layer covering at least part of the first metal trace in the first non-active area. In one embodiment, in at least part of the first non-active area, the protective layer at least partially covers the first metal trace. In one embodiment, the protective layer at least partially covers the first metal trace and extends in a direction away from the first metal trace until covering at least part of the first non-active area. In one embodiment, the protective layer is provided with first openings, an orthographic projection of the plurality of first openings on the substrate being misaligned with an orthographic projection of the first metal trace on the substrate. In one embodiment, the protective layer extends from the groove area to the first non-active area and covers at least part of the first metal trace in the first non-active area.

With reference to the first aspect, the non-active area includes a bendable area and a bonding area located on a side of the bendable area away from the active area, and the protective layer at least partially covers the first conductive layer located in the bonding area. In one embodiment, the first conductive layer includes metal trace layers, and further includes a third metal trace located in the bonding area third metal trace, the third metal trace and the first metal trace being located in the same or different metal trace layers, and the first metal trace being electrically connected to the third metal trace. In one embodiment, the bonding area includes a chip bonding area and/or a flexible printed circuit bonding area, the chip bonding area being provided with a first metal pin, and/or the flexible printed circuit bonding area being provided with a second metal pin, and the first metal pin and/or the second metal pin being electrically connected to the third metal trace. In one embodiment, the protective layer at least covers a side surface of the third metal trace. In one embodiment, the protective layer covers a side surface of the third metal trace and part of a surface of the third metal trace away from the substrate. In one embodiment, in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 μm. In one embodiment, in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 μm and less than or equal to 14.5 um.

With reference to the first aspect, the protective layer covers the bonding area, and is provided with first openings, an orthographic projection of the plurality of first openings on the substrate being misaligned with an orthographic projection of the first conductive layer on the substrate.

With reference to the first aspect, the first conductive layer further includes a second metal trace, and the protective layer further covers at least part of the second metal trace located in the non-active area. In one embodiment, the first metal trace includes a power supply voltage signal line, and the second metal trace includes at least one of a scan signal line and a data signal line. In one embodiment, the first conductive layer includes metal trace layers, and the first metal trace and the second metal trace are located in the same or different metal trace layers.

With reference to the first aspect, the display panel further includes a pixel defining layer located on a side of the array layer away from the substrate, the pixel defining layer extending from the active area to the non-active area, and the pixel defining layer in the non-active area being located on a side of the protective layer away from the substrate and at least partially covering the protective layer. In one embodiment, the pixel defining layer in the non-active area is provided with second openings, and the protective layer is provided with first openings, an orthographic projection of the plurality of second openings on the substrate at least partially overlapping with an orthographic projection of the plurality of first openings on the substrate. In one embodiment, the display panel further includes an encapsulation structure, the encapsulation structure including a first inorganic encapsulation layer, an organic encapsulation layer and a second inorganic encapsulation layer sequentially stacked in a direction facing away from the substrate, the second inorganic encapsulation layer extending from the active area to the non-active area. In one embodiment, the non-active area includes a dam area, the array layer includes at least one dam located in the dam area, the pixel defining layer extends from the active area to the dam area and covers at least part of the dam, and the second inorganic encapsulation layer is in contact with the pixel defining layer located on the dam. In one embodiment, the display panel further includes an isolation structure, the isolation structure including a first isolation portion and a second isolation portion sequentially stacked in a direction away from the substrate, an orthographic projection, on the substrate, of a side of the first isolation portion away from the substrate being within an orthographic projection of the second isolation portion on the substrate. In one embodiment, the isolation structure further includes a third isolation portion located on a side of the first isolation portion facing the substrate.

With reference to the first aspect, the array layer further includes a first insulating layer located on a side of the first conductive layer close to the substrate, and the protective layer covers at least part of the first metal trace and extends to cover part of a surface of the first insulating layer.

In a second aspect, an embodiment of the present application provides a display panel, having an active area and a non-active area at least partially surrounding the active area. The display panel includes: a substrate; an array layer located on one side of the substrate, the array layer including a first metal trace, the first metal trace being located at least in the non-active area; and a protective layer located on a side of the first metal trace facing away from the substrate and in the non-active area, the protective layer covering at least part of the first metal trace located in the non-active area.

With reference to the second aspect, a cladding of the protective layer on the first metal trace has a thickness greater than or equal to 1000 Å and less than or equal to 5000 Å. In one embodiment, a material of the protective layer includes at least one of an inorganic material and an organic material. In one embodiment, the first metal trace extends from the non-active area to the active area. In one embodiment, in a direction perpendicular to the substrate, the first metal trace includes a first metal layer, a second metal layer and a third metal layer sequentially stacked in a direction away from the substrate, and the protective layer at least covers a side surface of the second metal layer. In one embodiment, the protective layer covers a side surface of the first metal layer, a side surface of the second metal layer and a side surface of the third metal layer. In one embodiment, the protective layer extends from a side surface of the first metal layer to a surface of the third metal layer away from the substrate, and covers at least part of the surface of the third metal layer away from the substrate.

With reference to the second aspect, the non-active area includes a dam area and a groove area, the groove area being located on a side of the dam area away from the active area; and the array layer further includes a planarization layer located on the side of the first metal trace facing away from the substrate, the planarization layer having a groove in the groove area, the groove exposing part of the first metal trace, and the protective layer at least partially covering the first metal trace exposed at the groove. Preferably the protective layer at least partially covers the first metal trace and extends in a direction away from the first metal trace until covering the groove. In one embodiment, the protective layer is provided with first openings, an orthographic projection of the plurality of first openings on the substrate being misaligned with an orthographic projection of the first metal trace on the substrate.

With reference to the second aspect, the non-active area includes a bonding area located on a side of a bendable area away from the active area, and the array layer includes a third metal trace located in the bonding area, the first metal trace being electrically connected to the third metal trace. In one embodiment, the bonding area includes a chip bonding area and/or a flexible printed circuit bonding area, the chip bonding area being provided with a first metal pin, and/or the flexible printed circuit bonding area being provided with a second metal pin, and the first metal pin and/or the second metal pin being electrically connected to the third metal trace. In one embodiment, the protective layer at least covers a side surface of the third metal trace. In one embodiment, the protective layer covers a side surface of the third metal trace and part of a surface of the third metal trace away from the substrate. In one embodiment, in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 μm. In one embodiment, in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 μm and less than or equal to 14.5 um.

In a third aspect, an embodiment of the present application provides a display panel having an active area and a non-active area at least partially surrounding the active area. The non-active area includes a bonding area. The display panel includes: a substrate; an array layer located on one side of the substrate, the array layer including a third metal trace, the third metal trace being located in the bonding area; and a protective layer located on a side of the third metal trace facing away from the substrate and at least in the bonding area, the protective layer covering at least part of the third metal trace.

With reference to the third aspect, the bonding area includes a chip bonding area and/or a flexible printed circuit bonding area, the chip bonding area being provided with a first metal pin, and/or the flexible printed circuit bonding area being provided with a second metal pin, and the first metal pin and/or the second metal pin being electrically connected to the third metal trace. In one embodiment, the protective layer at least covers a side surface of the third metal trace. In one embodiment, the protective layer covers a side surface of the third metal trace and part of a surface of the third metal trace away from the substrate. In one embodiment, in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 μm. In one embodiment, in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 μm and less than or equal to 14.5 μm. In one embodiment, the protective layer covers the bonding area, and is provided with first openings, an orthographic projection of the plurality of first openings on the substrate being misaligned with an orthographic projection of the first conductive layer on the substrate.

In a fourth aspect, an embodiment of the present application provides a method for preparing a display panel, the method including: preparing a first conductive layer on a substrate, the first conductive layer including a first metal trace located at least in a non-active area; and preparing a protective layer on a side of the first conductive layer away from the substrate, where the protective layer is located in the non-active area and covers at least part of the first metal trace located in the non-active area.

With reference to the fourth aspect, preparing a protective layer on a side of the first conductive layer away from the substrate includes: depositing a protective material layer on the side of the first conductive layer away from the substrate; and patterning the protective material layer to obtain the protective layer. In one embodiment, patterning the protective material layer includes: etching the protective material layer to obtain the protective layer.

With reference to the fourth aspect, the method further includes: preparing a planarization layer on the side of the first conductive layer or the protective layer away from the substrate, the planarization layer extending from an active area to the non-active area in which the planarization layer is patterned to form a groove, and the first metal trace at the groove being covered by the protective layer.

With reference to the fourth aspect, the method further includes: preparing an electrode material layer on a side of the planarization layer away from the substrate, and patterning the electrode material layer to obtain an electrode layer; and preparing a pixel defining layer on a side of the electrode layer away from the substrate, the pixel defining layer extending from the active area to the non-active area, and the pixel defining layer in the non-active area covering the protective layer. In one embodiment, preparing a pixel defining layer on a side of the electrode layer away from the substrate includes: preparing an insulating material layer on the side of the electrode layer away from the substrate, and forming holes in the insulating material layer; preparing an isolation structure on a side of the insulating material layer away from the substrate; and patterning the insulating material layer to obtain the pixel defining layer.

With reference to the fourth aspect, before preparing the first conductive layer on the substrate, the method further includes: sequentially preparing at least one second conductive layer on the substrate, the at least one second conductive layer being separated by a second insulating layer; and preparing a first insulating layer on a side of the second conductive layer facing away from the substrate.

In a fifth aspect, an embodiment of the present application provide a display device including the display panel described above, or including a display panel prepared by the method described above.

### BRIEF DESCRIPTION OF THE DRAWINGS

FIG. 1a is a schematic cross-sectional view of a three-layer metal trace of a conductive layer that has not been etched.

FIG. 1b is a schematic cross-sectional view of the three-layer metal trace of the conductive layer after being etched.

FIG. 1c is a schematic view of the etched three-layer metal trace clad with a pixel defining layer.

FIG. 2 is a structural schematic view of a display panel according to an embodiment of the present application.

FIG. 3 is a first structural schematic cross-sectional view of the display panel shown in FIG. 2 along line B1B2.

FIG. 4a is a first structural schematic cross-sectional view of the display panel shown in FIG. 2 along the line C1C2.

FIG. 4b is a second structural schematic cross-sectional view of the display panel shown in FIG. 2 along line C1C2.

FIG. 4c is a third structural schematic cross-sectional view of the display panel shown in FIG. 2 along line C1C2.

FIG. 4d is a fourth structural schematic cross-sectional view of the display panel shown in FIG. 2 along the line C1C2.

FIG. 5 is a second structural schematic cross-sectional view of the display panel shown in FIG. 2 along line B1B2.

FIG. 6 is a third structural schematic cross-sectional view of the display panel shown in FIG. 2 along line B1B2.

FIG. 7a is a first structural schematic cross-sectional view of the display panel shown in FIG. 2 along the line D1D2.

FIG. 7b is a schematic view of a third metal trace electrically connected to a metal pin in a chip bonding area.

FIG. 7c is a schematic view of the third metal trace electrically connected to a metal pine in a flexible printed circuit bonding area.

FIG. 8 is a fourth structural schematic cross-sectional view of the display panel shown in FIG. 2 along line B1B2.

FIGS. 9a and 9b are enlarged views of region M in FIG. 4a.

FIG. 10 is a schematic flow chart of a method for preparing a display panel according to an embodiment of the present application.

FIG. 11 is a schematic flow chart of a method for preparing a display panel according to another embodiment of the present application.

FIG. 12 is a structural schematic view of a display device according to an embodiment of the present application.

### DETAILED DESCRIPTION OF EMBODIMENTS

The embodiments of the present application will be clearly and completely described below with reference to the drawings in the embodiments of the present application. Apparently, the embodiments described are merely some rather than all of the embodiments of the present application.

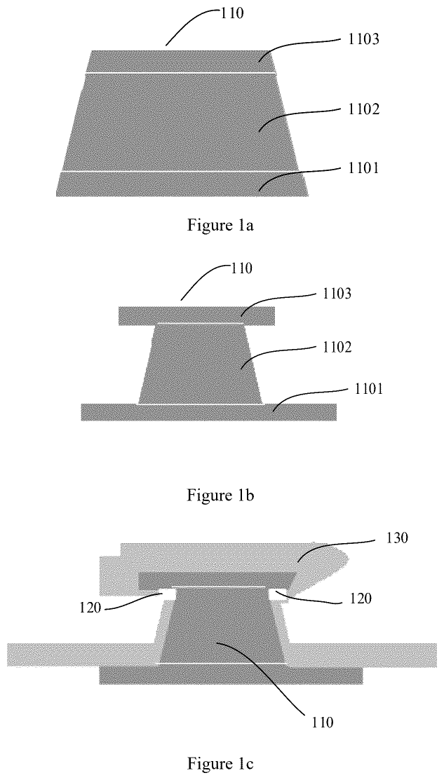

In general, signal lines in a display panel need to extend from an active area to a non-active area to be electrically connected to an integrated circuit (IC) or a flexible printed circuit (FPC). The signal lines of the display panel are distributed in conductive layers of an array substrate, and insulating layers are provided between the plurality of conductive layers to isolate adjacent conductive layers. A planarization layer covers a surface of the topmost conductive layer. The planarization layer extends from the active area to the non-active area. To prevent moisture from the periphery of a screen body from invading the screen body, the planarization layer is generally interrupted in the non-active area, and the topmost conductive layer is exposed in this case. In general, the conductive layer is made of three layers of metal. As shown in FIG. 1a, a metal line 110 of the conductive layer includes a first layer of metal 1101, a second layer of metal 1102, and a third layer of metal 1103 stacked. The first layer of metal 1102 and the third layer of metal 1103 are made of titanium, and the middle layer of metal is made of aluminum 1102.

The inventors have found by researches that during subsequent film layer patterning (e.g., etching a planarization layer, etching an anode layer, etc.), the exposed conductive layer (i.e., the metal line 110) will be etched, especially the second layer of metal 1102 is heavily side etched, forming an undercut structure (as shown in FIG. 1b). When this area is clad with an inorganic layer 130, it is likely to form holes (e.g., holes 120 shown in FIG. 1c) in side etching positions, and moisture intrusion may cause corrosion of the metal line, affecting the reliability of the display panel.

In addition, this conductive layer includes a power supply voltage signal line (e.g., ELVSS or ELVDD), and a voltage difference of a power supply voltage signal is relatively large. For example, in a stacked device (e.g., a Tandem device), a voltage difference of ELVDD and/or ELVSS is larger than that of a single-layer device. When performing a high-temperature and high-humidity reliability test, the power supply voltage signal line is more susceptible to electrochemical corrosion, affecting the reliability of the display panel.

In view of the above problems, in a first aspect, an embodiment of the present application provides a display panel, having an active area and a non-active area at least partially surrounding the active area. The display panel includes: a substrate; an array layer located on one side of the substrate, the array layer including a first conductive layer, the first conductive layer including a first metal trace, the first metal trace being located at least in the non-active area; and a protective layer located on a side of the first conductive layer facing away from the substrate and in the non-active area, the protective layer covering at least part of the first metal trace located in the non-active area. Here, by “the protective layer covering at least part of the first metal trace located in the non-active area”, it is meant that the protective layer covers at least one section of the first metal trace located in the non-active area, or the protective layer covers a side surface of the first metal trace located in the non-active area. By way of example, the non-active area includes a dam area and a groove area, and the protective layer may cover only the first metal trace in the groove area. In an embodiment of the present application, the first conductive layer includes at least one metal trace layer, on which the first metal trace is located. Different metal trace layers are electrically connected to each other by means of via holes. In the embodiments of the present application, the protective layer is used to protect at least part of the first metal trace in the non-active area to ensure that the first metal trace will not be affected by a subsequent wet process, and the first metal trace can still maintain its original form (e.g., as shown in FIG. 1a), without the formation of an undercut structure, the protective layer and a subsequent film layer can form a good cladding of the first metal trace, avoiding the formation of holes, and the first metal trace can be further prevented from being electrochemically corroded during a reliability test, to improve the reliability of the display panel.

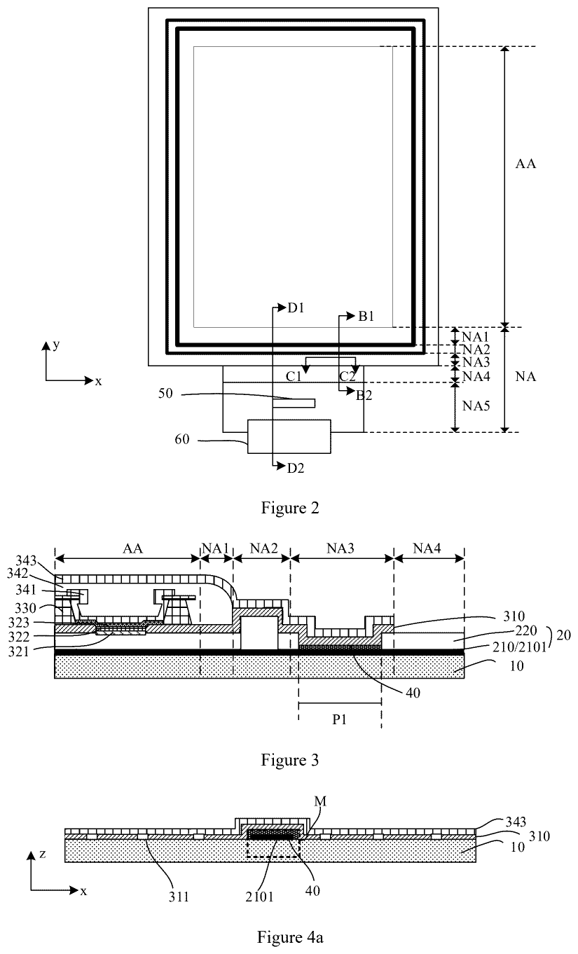

FIG. 2 is a structural schematic view of a display panel according to an embodiment of the present application. FIG. 3 is a first structural schematic cross-sectional view of the display panel shown in FIG. 2 along line B1B2. As shown in FIGS. 2 and 3, the display panel has an active area AA and a non-active area NA at least partially surrounding the active area AA. The display panel includes a substrate 10, and an array layer 20 located on one side of the substrate. The array layer 20 includes a first conductive layer 210. The first conductive layer 210 includes a first metal trace 2101. The first metal trace 2101 is located at least in the non-active area NA. The protective layer 40 is located on a side of the first conductive layer 210 facing away from the substrate 10 and in the non-active area NA, and the protective layer 40 covers at least part of the first metal trace 2101 located in the non-active area NA. Here, by “the protective layer 40 covers at least part of the first metal trace 2101 located in the non-active area NA”, it is meant that the protective layer 40 covers at least one section of the first metal trace 2101 located in the non-active area NA. In an embodiment of the present application, the first metal trace 2101 extends from the non-active area NA to the active area AA.

In an embodiment of the present application, the protective layer 40 is located only in the non-active area AA. Since the first conductive layer 210 in the active area AA is covered by an organic film layer (planarization layer), the influence of the wet process on the first conductive layer 210 can be reduced or avoided. Moreover, the encapsulation effect in the active area AA is superior to the non-active area NA, moisture is not easy to enter the active area, and even in high-temperature and high-humidity environments, the first metal trace 2101 is also not susceptible to corrosion. Furthermore, when the protective layer 40 extends to the active area AA, gas may be unlikely to be discharged during a high-temperature baking process, resulting in peeling of a film layer.

In an embodiment of the present application, a cladding of the protective layer 40 on the first metal trace 2101 has a thickness (e.g., H in FIG. 9b) greater than or equal to 1000 Å and less than or equal to 5000 Å. By way of example, the thickness of the cladding of the protective layer 40 on the surface of the first metal trace 2101 is 1000 Å, 1500 Å, 2000 Å, 3000 Å, 4000 Å, 5000 Å. When the protective layer 40 is too thin, the first metal trace 2101 may not be fully clad and thus cannot be completely protected. When the protective layer 40 is too thick, higher energy may be required during etching, it is likely to damage other film layers. Therefore, the protective layer 40 needs to be chosen to be of an appropriate thickness. Furthermore, in the embodiments of the present application, since the first metal trace 2101 has not yet been etched by an etching solution and is still in its original form (i.e., the form shown in FIG. 1a), it is less difficult to deposit the protective layer 40 on the surface of the first metal trace 2101, and the protective layer 40 does not need to be too thick to achieve a good cladding of the first metal trace 2101.

In an embodiment of the present application, a material of the protective layer 40 includes at least one of an inorganic material and an organic material. By way of example, the inorganic material includes at least one of silicon oxide and silicon nitride. The inorganic material will not be eroded by the etching solution, and the first metal trace 2101 can be protected from being etched by the etching solution during a subsequent film layer preparation process. In addition, the use of the inorganic material can also insulate moisture, further avoiding corrosion of the first metal trace 2101 during a reliability test under high-temperature and high-humidity conditions.

With continued reference to FIG. 3, the non-active area NA includes a dam area NA2, a groove area NA3 and a bendable area NA4. The groove area NA3 is located on a side of the dam area NA2 away from the active area AA, and the bendable area NA4 is located on a side of groove area NA3 away from dam area NA2. The array layer 20 further includes a planarization layer 220. The planarization layer 220 is located on a side of the first conductive layer 210 facing away from the substrate 10, and in the groove area NA3, the planarization layer 220 has a groove P1. That is, the planarization layer 220 is the groove area NA3 is etched away to cut off an intrusion path of external moisture. The groove P1 exposes part of the first metal trace 2101, and the protective layer 40 at least partially covers the first metal trace 2101 exposed at the groove P1. Here, by “at least partially covers”, it is meant that the protective layer 40 covers at least the side surface of the first metal trace 2101. For further description, reference is made to FIGS. 9a and 9b in the embodiments of the present application. In one embodiment, in a direction parallel to the substrate 10, a width of the groove P1 is less than or equal to a width of the groove area NA3. In the embodiments of the present application, since the side surface of the first metal trace 2101 is susceptible to side etching, the protective layer 40 at least partially covering the exposed first metal trace 2101 (e.g., at least covering the side surface of the first metal trace 2101) can protect the exposed first metal trace 2101 from being eroded by the etching solution, to improve the reliability of the display panel.

In one embodiment, at the groove P1, the protective layer only at least partially covers the first metal trace. In one embodiment, at the groove, the protective layer at least partially covers the first metal trace and extends in a direction away from the first metal trace until covering the entire groove P1. Since the protective layer is made of an inorganic material, the array layer is provided with an organic film layer on a side of the protective layer close to the substrate. The organic film layer will generate a gas during high-temperature baking. When the protective layer covers an excessively large area, the gas cannot be discharged, resulting in separation of the film layer. Therefore, the protective layer is provided with first openings, and an orthographic projection of the plurality of first openings on the substrate is misaligned with an orthographic projection of the first metal trace on the substrate. With such an arrangement, not only can the gas be vented, but the first metal trace can also be prevented from being exposed to the etching solution in a subsequent process.

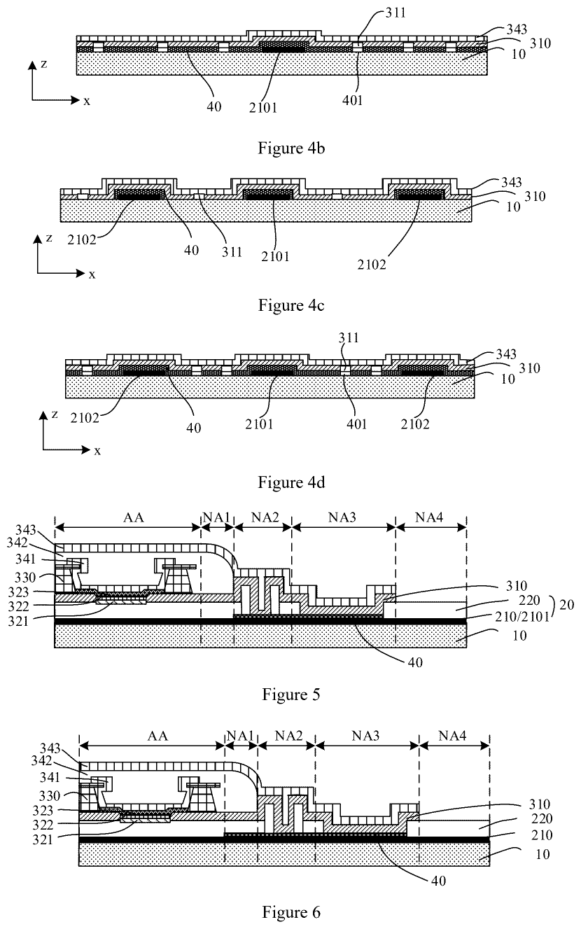

By way of example, FIG. 4a is a first structural schematic cross-sectional view of the display panel shown in FIG. 2 along the line C1C2. FIG. 4b is a second structural schematic cross-sectional view of the display panel shown in FIG. 2 along line C1C2. The line C1C2 is located at the groove P1 in the groove area NA3. As shown in FIG. 4a, the first conductive layer 210 includes a first metal trace 2101, and the protective layer 40 only at least partially covers the first metal trace 2101 (e.g., at least covering the side surface of the first metal trace 2101). As shown in FIG. 4b, the first conductive layer 210 includes the first metal trace 2101, and the protective layer 40 at least partially covers the first metal trace 2101 and extends in the direction away from the first metal trace 2101 (i.e., in the x-direction in FIG. 4b) until covering the entire area of the groove P1. As shown in FIG. 4b, the protective layer 40 is provided with first openings 401, an orthographic projection of the plurality of first openings 401 on the substrate 10 being misaligned with an orthographic projection of the first metal trace 2101 on the substrate 10.

In an embodiment of the present application, the first metal trace 2101 includes a power supply voltage signal line (e.g., ELVSS or ELVDD). Compared with other signal lines (e.g., a scan signal line and a data signal line), the power supply voltage signal line is more susceptible to electrochemical corrosion during a reliability test. The use of the protective layer 40 to protect the first metal trace 2101 can avoid or reduce the electrochemical corrosion of the first metal trace 2101. In one embodiment, the first conductive layer 210 further includes a second metal trace (second metal trace 2102 in FIG. 4c or 4d). The second metal trace includes signal lines other than the power supply voltage signal line, e.g., a scan signal line and a data signal line. In one embodiment, the first conductive layer 210 includes metal trace layers, and the first metal trace 2101 and the second metal trace are located in the same or different metal trace layers. The protective layer 40 further covers at least part of the second metal trace located in the non-active area NA (e.g., the groove area NA3). That is, the protective layer 40 covers the entire metal trace of the first conductive layer 210 located in the non-active area NA (e.g., the groove area NA3).

In one embodiment, FIG. 4c is a third structural schematic cross-sectional view of the display panel shown in FIG. 2 along line C1C2. FIG. 4d is a fourth structural schematic cross-sectional view of the display panel shown in FIG. 2 along the line C1C2. As shown in FIGS. 4c and 4d, the first conductive layer 210 includes a first metal trace 2101 and a second metal trace 2102. The first metal trace 2101 and the second metal trace 2102 are located in the same or different metal trace layers. In FIG. 4c, the protective layer 40 covers only the first metal trace 2101 and the second metal trace 2102. In FIG. 4d, the protective layer 40 covers the first metal trace 2101 and the second metal trace 2102 and extends in the direction away from the first metal trace 2101 and/or the second metal trace 2102 (i.e., in the x-direction in FIG. 4d) until covering the entire area of the groove P1. In this case, an orthographic projection of the protective layer 40 on the substrate 10 overlaps with an orthographic projection of the groove P1 on the substrate 10. As shown in FIG. 4d, the protective layer 40 is provided with first openings 401. An orthographic projection of the plurality of first openings 401 on the substrate 10 does not overlap with orthographic projections of the first metal trace 2101 and the second metal trace 2102 on the substrate 10.

With continued reference to FIG. 3, the display panel further includes a pixel defining layer 310 located on a side of the array layer 20 away from the substrate 10. The pixel defining layer 310 extends from the active area AA to the non-active area NA, and the pixel defining layer 310 in the non-active area NA is located on a side of the protective layer 40 away from the substrate 10 and at least partially covers the protective layer 40. In the active area AA, the pixel defining layer 310 encloses a pixel opening. The display panel further includes a light-emitting device at least partially located within the pixel opening. The light-emitting device includes a first electrode 321, a light-emitting unit 322 and a second electrode 323 stacked in sequence. By way of example, the first electrode 321 is an anode, and the second electrode 323 is a cathode. In one embodiment, the first electrode 321 is a cathode, and the second electrode 323 is an anode.

The display panel further includes an isolation structure 330 located on a side of the pixel defining layer 310 away from the substrate 10. The isolation structure 330 is located in the active area AA, and the isolation structure 330 includes isolation openings in communication with the pixel opening. In an embodiment of the present application, the isolation structure 330 includes a first isolation portion and a second isolation portion sequentially stacked in the direction away from the substrate 10. An orthographic projection, on the substrate 10, of a side of the first isolation portion away from the substrate 10 is within an orthographic projection of the second isolation portion on the substrate 10. In one embodiment, the isolation structure 330 further includes a third isolation portion located on a side of the first isolation portion facing the substrate 10. In one embodiment, in the direction away from the substrate 10, the isolation structure 330 includes molybdenum/aluminum/titanium stacked in sequence. The isolation structure is electrically connected to the first metal trace 2101, and the second electrode 323 is coupled to the isolation structure (e.g. the molybdenum layer or the aluminum layer) to achieve electrical connection.

The composition, preparation and the like of the isolation structure 330 are further described in Patent No. CN 118251982 A, US202410864269.8, Patent No. PCT/CN2024/098407, Patent No. PCT/CN2024/102783, Patent No. PCT/CN2024/098217, Patent No. PCT/CN2024/100935, Patent No. PCT/CN2024/102785, Patent No. PCT/CN2024/099419, Patent No. PCT/CN2024/099072, and Patent No. CN 116685174 A, which are incorporated in the present application by reference in their entireties.

The display panel further includes an encapsulation structure. The encapsulation structure includes a first inorganic encapsulation layer 341, an organic encapsulation layer 342 and a second inorganic encapsulation layer 343 sequentially stacked in the direction facing away from the substrate 10. The first inorganic encapsulation layer 341 encapsulates a pixel unit, and is located in the active area AA. In an embodiment of the present application, the pixel defining layer 310 includes an inorganic material, and in the non-active area NA, the first inorganic encapsulation layer 341 is omitted, and the second inorganic encapsulation layer 343 is in direct contact with the pixel defining layer 310, to reduce the number of film layers and facilitating bending. The first inorganic encapsulation layer 341 includes first encapsulation units corresponding to light-emitting devices on a one-to-one basis. An orthographic projection of the first encapsulation unit on the substrate 10 covers an orthographic projection of the light-emitting device on the substrate. At least part of the first encapsulation unit is located in the pixel opening.

With continued reference to FIG. 3, the non-active area NA includes the dam area NA2, and the array layer 20 includes at least one dam 221 located in the dam area NA2. The organic encapsulation layer 342 extends from the active area AA to the non-active area NA and terminates at the dam 221. The pixel defining layer 310 extends from the active area AA to the dam area NA2 and covers at least part of the dam, and the second inorganic encapsulation layer 343 is in contact with the pixel defining layer 310 located on the dam 221. Since both the pixel defining layer 310 and the second inorganic encapsulation layer 343 are made of inorganic materials, the film layer separation probability can be reduced, while the encapsulation effect is improved, to improve the reliability of the display panel.

Since the pixel defining layer 310 is made of an inorganic material, in the non-active area NA, the pixel defining layer 310 covers the entire surface, and when the gas generated during the high-temperature baking cannot be removed in a timely manner, it is possible to result in film layer separation. In one embodiment, as shown in FIGS. 4a-4d, the pixel defining layer 310 in the non-active area NA is provided with second openings 311. In the area where the pixel defining layer 310 covers the protective layer 40, an orthographic projection of the plurality of second openings 311 on the substrate 10 at least partially overlaps with the orthographic projection, on the substrate 10, of the plurality of first openings 401 provided in the protective layer 40. With such an arrangement, the gas produced during the high-temperature baking can be guaranteed to be discharged smoothly, to improve the reliability of the display panel.

In one embodiment, the protective layer 40 covers at least part of the first metal trace 2101 in the dam area NA2, and in at least part of the dam area NA2, the protective layer 40 at least partially covers the first metal trace 2101 (and the second metal trace 2102). Here, by “at least partially covers”, it is meant that the protective layer 40 covers at least the side surface of the first metal trace 2101 (and the second metal trace 2102). For further description, reference is made to FIGS. 9a and 9b in the embodiments of the present application. In one embodiment, in at least part of the dam area NA2, the protective layer 40 only at least partially covers the first metal trace 2101 (and the second metal trace 2102). In one embodiment, in at least part of the dam area NA2, the protective layer 40 at least partially covers the first metal trace 2101 (and the second metal trace 2102) and extends in a direction away from the first metal trace 2101 (and the second metal trace 2102) until covering at least part of the dam area NA2. In this case, in order to ensure a smooth discharge of the gas generated in the film layer, the protective layer 40 is provided with first openings 401. An orthographic projection of the plurality of first openings 401 on the substrate 10 is misaligned with the orthographic projection of the first metal trace 2101 (and the second metal trace 2102) on the substrate 10. In one embodiment, the dam area NA2 includes at least two dams. When the first metal trace 2101 (and the second metal trace 2102) is exposed due to the planarization layer 220 between adjacent dams being etched away, the exposed first metal trace 2101 (and the second metal trace 2102) will be etched in a subsequent process. Therefore, the protective layer 40 at least partially covers the first metal trace 2101 (and the second metal trace 2102) located between adjacent dams. In one embodiment, the protective layer 40 extends from the groove area NA3 to the dam area NA2 and covers at least part of the first metal trace 2101 (and the second metal trace 2102) in the dam area NA2 to simplify the preparation process.

By way of example, FIG. 5 is a second structural schematic cross-sectional view of the display panel shown in FIG. 2 along line B1B2. The display panel shown in FIG. 5 differs from the panel of FIG. 3 in that the protective layer 40 extends from the groove area NA3 to the dam area NA2 and covers the first metal trace 2101 (and the second metal trace 2102) in the dam area NA2. In the dam area NA2, the protective layer 40 at least partially covers the first metal trace 2101 (and the second metal trace 2102). For example, in the dam area NA2, the protective layer 40 only at least partially covers the first metal trace 2101 (and the second metal trace 2102). In one embodiment, in the dam area NA2, the protective layer 40 at least partially covers the first metal trace 2101 (and the second metal trace 2102) and extends in the direction away from the first metal trace 2101 (and the second metal trace 2102) until covering the entire dam area NA2. In this case, the protective layer 40 is provided with first openings 401. An orthographic projection of the plurality of first openings 401 on the substrate 10 is misaligned with the orthographic projection of the first metal trace 2101 (and the second metal trace 2102) on the substrate 10.

In one embodiment, the non-active area NA further includes a first non-active area NA1. The first non-active area NA1 is located between the dam area NA2 and the active area AA, and the protective layer 40 covers at least part of the first metal trace 2101 (and the second metal trace 2102) in the first non-active area NA1. In at least part of the first non-active area NA1, the protective layer 40 at least partially covers the first metal trace 2101 (and the second metal trace 2102). For example, in at least part of the first non-active area NA1, the protective layer 40 only at least partially covers the first metal trace 2101 (and the second metal trace 2102). In one embodiment, in at least part of the first non-active area NA1, the protective layer 40 at least partially covers the first metal trace 2101 (and the second metal trace 2102) and extends in a direction away from the first metal trace 2101 (and the second metal trace 2102) until covering at least part of the first non-active area NA1. In this case, in order to ensure a smooth discharge of the gas generated in the film layer, the protective layer 40 is provided with first openings 401. An orthographic projection of the plurality of first openings 401 on the substrate 10 is misaligned with the orthographic projection of the first metal trace 2101 (and the second metal trace 2102) on the substrate 10. In one embodiment, the protective layer 40 extends from the groove area NA3 to the first non-active area NA1 and covers at least part of the first metal trace 2101 in the first non-active area NA1.

By way of example, FIG. 6 is a third structural schematic cross-sectional view of the display panel shown in FIG. 2 along line B1B2. The display panel shown in FIG. 6 differs from the panel shown in FIG. 3 in that the protective layer 40 extends from the groove area NA3 to the first non-active area NA1 and covers the first metal trace 2101 (and the second metal trace 2102) in the first non-active area NA1. In the first non-active area NA1, the protective layer 40 at least partially covers the first metal trace 2101 (and the second metal trace 2102). For example, in the first non-active area NA1, the protective layer 40 only at least partially covers the first metal trace 2101 (and the second metal trace 2102). In one embodiment, in the first non-active area NA1, the protective layer 40 at least partially covers the first metal trace 2101 (and the second metal trace 2102) and extends in a direction away from the first metal trace 2101 (and the second metal trace 2102) until covering the entire first non-active area NA1. In this case, the protective layer 40 is provided with first openings 401. An orthographic projection of the plurality of first openings 401 on the substrate 10 is misaligned with the orthographic projection of the first metal trace 2101 (and the second metal trace 2102) on the substrate 10.

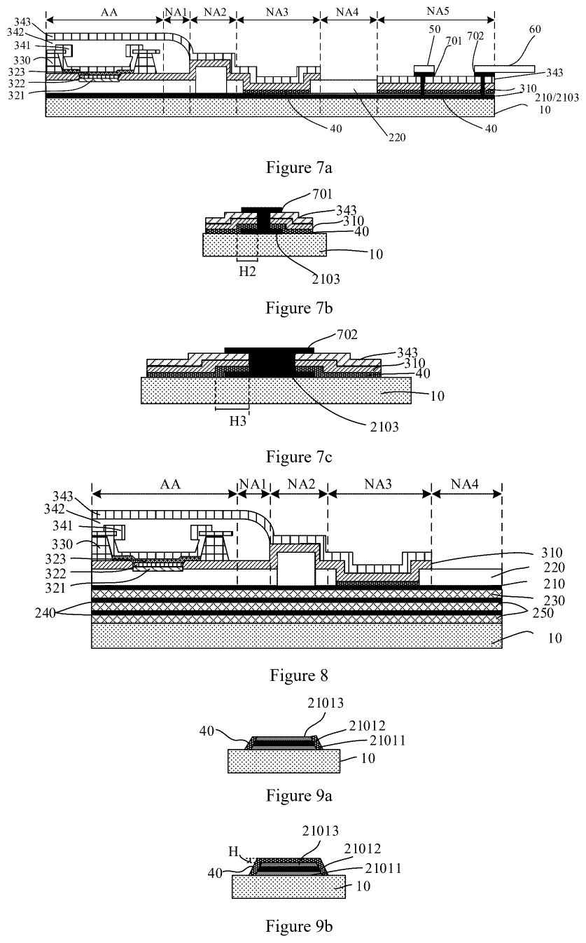

FIG. 7a is a first structural schematic cross-sectional view of the display panel shown in FIG. 2 along the line D1D2. The display panel shown in FIG. 7a differs from the panel shown in FIG. 3 in that the non-active area NA further includes a bonding area NA5, which bonding area NA5 is located on a side of the bendable area NA4 away from the active area AA. The bonding area NA5 includes a chip bonding area and/or a flexible printed circuit bonding area. In the chip bonding area, the display panel is provided with a first metal pin 701, and the display panel and a chip (integrated circuit, IC) 50 are bonded by means of the first metal pin 701 in the chip bonding area. In the flexible printed circuit bonding area, the display panel is provided with a second metal pin 702, and the display panel and the flexible printed circuit (FPC) 60 are bonded by means of the second metal pin 702 in the flexible printed circuit bonding area. In one embodiment, the display panel further includes a touch layer including a touch metal layer. The first metal pin and the second metal pin may be located at the touch metal layer.

As shown in FIG. 7a, in the bonding area NA5, a side of the first conductive layer 210 away from the substrate 10 is not covered by the planarization layer 220. Therefore, the metal trace on the first conductive layer 210 needs to be covered by the protective layer 40 to prevent the metal trace from being etched by the etching solution in a subsequent process. Since the first conductive layer 210 in the bonding area includes metal traces, to ensure good contact between the display panel and the IC or FPC, all of the exposed metal traces of the first conductive layer 210 need to be clad to avoid poor contact caused by etching of the metal traces. Therefore, the protective layer 40 at least partially covers the first conductive layer 210 located in the bonding area NA5, that is, the protective layer 40 at least partially covers all of the metal traces of the first conductive layer 210 located in the bonding area NA5.

In one embodiment, the first conductive layer 210 includes metal trace layers, and the first conductive layer 210 further includes a third metal trace 2103. The third metal trace 2103 is located in the bonding area NA5, and the third metal trace and the first metal trace 2101 are located in the same or different metal trace layers. In an embodiment of the present application, the first metal trace 2101 is electrically connected to the third metal trace 2103. It will be appreciated that the electrical connection structure of the first metal trace 2101 and the third metal trace 2103 is not shown in the figures for simplicity, and can select the manner and position of the electrical connection according to actual requirements.

In one embodiment, the display panel is provided with a first metal pin 701 in the chip bonding area, and the display panel is provided with a second metal pin 702 in the flexible printed circuit bonding area. The first metal pin 701 and the second metal pin 702 are electrically connected to the third metal trace 2103. In an embodiment of the present application, the protective layer 40 cannot cover the entire surface of the third metal trace 2103 away from the substrate 10 and the third metal trace 2103 is electrically connected to the first metal pins 701 and 702. In one embodiment, the protective layer 40 at least covers a side surface of the third metal trace 2103. For example, the protective layer 40 covers the side surface of the third metal trace 2103 and part of a surface of the third metal trace away from the substrate 10. FIG. 7b is a schematic view of a third metal trace electrically connected to the first metal pin in the chip bonding area. FIG. 7c is a schematic view of the third metal trace electrically connected to the second metal pine in the flexible printed circuit bonding area. As shown in FIG. 7b, in the chip bonding area, a projection, on the substrate 10, of the protective layer 40, that covers the side surface of the third metal trace 2103 and part of the surface of the third metal trace away from the substrate, in a cross-sectional direction of the third metal trace 2103 has a length H2 greater than or equal to 0.5 μm and less than or equal to 10.5 um. By way of example, the length H2 of the projection, on the substrate 10, of the protective layer 40, that covers the side surface of the third metal trace 2103 and part of the surface of the third metal trace away from the substrate is 0.5 μm, 2.5 μm, 3 μm, 3.5 μm, 4 μm, 4.6 um, 5 μm, 5.5 μm, 8 μm, or 10.5 um. As shown in FIG. 7b, in the flexible printed circuit bonding area, a projection, on the substrate 10, of the protective layer 40, that covers the side surface of the third metal trace 2103 and part of the surface of the third metal trace away from the substrate, in a cross-sectional direction of the third metal trace 2103 has a length H3 greater than or equal to 0.5 μm and less than or equal to 14.5 um. By way of example, the length H3 of the projection, on the substrate 10, of the protective layer 40, that covers the side surface of the third metal trace 2103 and part of the surface of the third metal trace away from the substrate is 0.5 μm, 2.5 μm, 4.5 μm, 5.5 μm, 7 μm, 8 um, 9.5 μm, 10.5 um, 12 μm, or 14.5 um. It will be appreciated that the projection lengths H2 and H3 herein are exemplary only and do not limit the scope of protection of the present application. When applied to products of different sizes, the projection lengths H2 and H3 can be determined according to actual requirements, as long as the protective layer 40 is guaranteed to adequately protect the third metal trace 2103 in the bonding area NA5, to ensure that the third metal trace 2103 will not be affected by a subsequent wet process, and the third metal trace can still maintain its original form (e.g., as shown in FIG. 1a), without the formation of an undercut structure, the protective layer and a subsequent film layer can form a good cladding of the third metal trace, avoiding the formation of holes, and the third metal trace can be further prevented from being electrochemically corroded during a reliability test, to improve the reliability of the display panel, while the third metal trace 2103 can be electrically connected to the first metal pin 701/second metal pin 702.

In one embodiment, in the bonding area NA5, the protective layer 40 only at least partially covers the first conductive layer 210. In one embodiment, in the bonding area NA5, the protective layer 40 covers the entire bonding area NA5. In order to ensure a smooth discharge of the gas, the protective layer 40 is provided with first openings 401. An orthographic projection of the plurality of first openings 401 on the substrate 10 is misaligned with the orthographic projection of the first conductive layer 210 on the substrate 10.

When the bendable area NA4 needs to be bent, the inorganic material is relatively brittle and is likely to be broken when bending, and therefore the bendable area NA4 cannot contain the inorganic material. That is, the protective layer 40 cannot cover the bendable area NA4. In addition, since both the pixel defining layer 310 and the second inorganic encapsulation layer 343 are made of inorganic materials, the materials of the pixel defining layer 310 and the second inorganic encapsulation layer 343 cannot be included in the bendable area NA4.

FIG. 8 is a fourth structural schematic cross-sectional view of the display panel shown in FIG. 2 along line B1B2. The display panel shown in FIG. 8 differs from the display panel shown in FIG. 3 in that the array layer 20 further includes a first insulating layer 230. The first insulating layer 230 is located on a side of the first conductive layer 210 close to the substrate 10, and the protective layer 40 covers at least part of the first metal trace 2101 and extends to cover part of a surface of the first insulating layer 230. The array layer 20 further includes at least one second conductive layer 240 at least partially stacked. The second conductive layers 240 are located on the side of the first conductive layer 210 close to the substrate, the second conductive layers 240 are separated by a second insulating layer 250. The first insulating layer 230, the second conductive layer 240, and the second insulating layer 250 are conventional arrangements of array layers, and will not be described in detail in the embodiments of the present application.

FIGS. 9a and 9b are enlarged views of region M in FIG. 4a. As shown in FIGS. 9a and 9b, in a direction perpendicular to the substrate, the first metal trace 2101 includes a first metal layer 21011, a second metal layer 21012 and a third metal layer 21013 sequentially stacked in a direction away from the substrate 10. In one embodiment, the materials of the first metal layer 21011 and the third metal layer 21013 include titanium or molybdenum, and the material of the second metal layer 21012 includes aluminum. Since aluminum is easily corroded by the etching solution, the protective layer 40 covers at least a side surface of the second metal layer 21012 in an embodiment of the present application. As shown in FIG. 9a, the protective layer 40 covers a side surface of the first metal layer 21011, the side surface of the second metal layer 21012, and a side surface of the third metal layer 21013. As shown in FIG. 9b, the protective layer extends from the side surface of the first metal layer 21011 to a surface of the third metal layer 21013 away from the substrate 10, and covers at least part of the surface of the third metal layer 21013 away from the substrate 10. It will be appreciated that the structure of the second metal trace 2102 and/or the third metal traces 2103 is the same as the structure of the first metal trace 2101 and will not be described here again.

In a second aspect, an embodiment of the present application provides a display panel, including an active area and a non-active area at least partially surrounding the active area. The display panel includes: a substrate; an array layer located on one side of the substrate, the array layer including a first metal trace, the first metal trace being located in the non-active area; and a protective layer located on a side of the first metal trace facing away from the substrate and in the non-active area, the protective layer covering at least part of the first metal trace located in the non-active area.

In one embodiment, a cladding of the protective layer on the first metal trace has a thickness greater than or equal to 1000 Å and less than or equal to 5000 Å.

In one embodiment, a material of the protective layer includes at least one of an inorganic material and an organic material.

In one embodiment, the first metal trace extends from the non-active area to the active area.

In one embodiment, in a direction perpendicular to the substrate, the first metal trace includes a first metal layer, a second metal layer and a third metal layer sequentially stacked in a direction away from the substrate, and the protective layer at least covers a side surface of the second metal layer.

In one embodiment, the protective layer covers a side surface of the first metal layer, a side surface of the second metal layer and a side surface of the third metal layer.

In one embodiment, the protective layer extends from a side surface of the first metal layer to a surface of the third metal layer away from the substrate, and covers at least part of the surface of the third metal layer away from the substrate.

In one embodiment, the non-active area includes a dam area and a groove area, the groove area being located on a side of the dam area away from the active area; and the array layer further includes a planarization layer located on the side of the first metal trace facing away from the substrate, the planarization layer having a groove in the groove area, the groove exposing part of the first metal trace, and the protective layer at least partially covering the first metal trace exposed at the groove.

In one embodiment, the protective layer at least partially covers the first metal trace and extends in a direction away from the first metal trace until covering the groove.

In one embodiment, the protective layer is provided with first opening, an orthographic projection of the plurality of first openings on the substrate being misaligned with an orthographic projection of the first metal trace on the substrate.

In one embodiment, the non-active area includes a bendable area and a bonding area located on a side of the bendable area away from the active area.

The array layer includes a third metal trace located in the bonding area, the first metal trace and the third metal trace being located in the same or different metal traces, and the first metal trace being electrically connected to the third metal trace.

In one embodiment, the bonding area includes a chip bonding area and/or a flexible printed circuit bonding area, the chip bonding area being provided with a first metal pin, and/or the flexible printed circuit bonding area being provided with a second metal pin, and the first metal pin and/or the second metal pin being electrically connected to the third metal trace.

In one embodiment, the protective layer at least covers a side surface of the third metal trace.

In one embodiment, the protective layer covers a side surface of the third metal trace and part of a surface of the third metal trace away from the substrate.

In one embodiment, in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 um.

In one embodiment, in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 um and less than or equal to 14.5 um.

For further description of this display panel, reference is made to the description of other embodiments of the present application.

In a third aspect, an embodiment of the present application provides a display panel including an active area and a non-active area at least partially surrounding the active area. The non-active area includes a bonding area. The display panel includes: a substrate; an array layer located on one side of the substrate, the array layer including a third metal trace, the third metal trace being located in the bonding area; and a protective layer located on a side of the third metal trace facing away from the substrate and at least in the bonding area, the protective layer covering at least part of the third metal trace.

In one embodiment, the bonding area includes a chip bonding area and/or a flexible printed circuit bonding area, the chip bonding area and/or the flexible printed circuit bonding area being provided with metal pins electrically connected to the third metal trace.

In one embodiment, the protective layer at least covers a side surface of the third metal trace.

In one embodiment, the protective layer covers a side surface of the third metal trace and part of a surface of the third metal trace away from the substrate.

In one embodiment, in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 um.

In one embodiment, in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 um and less than or equal to 14.5 um.

In one embodiment, the protective layer covers the bonding area, and is provided with first opening, an orthographic projection of the plurality of first openings on the substrate being misaligned with an orthographic projection of the third metal trace on the substrate.

For further description of this display panel, reference is made to the description of other embodiments of the present application.

In a fourth aspect, an embodiment of the present application provides a method for preparing a display panel. The method is used for preparing the display panel described above.

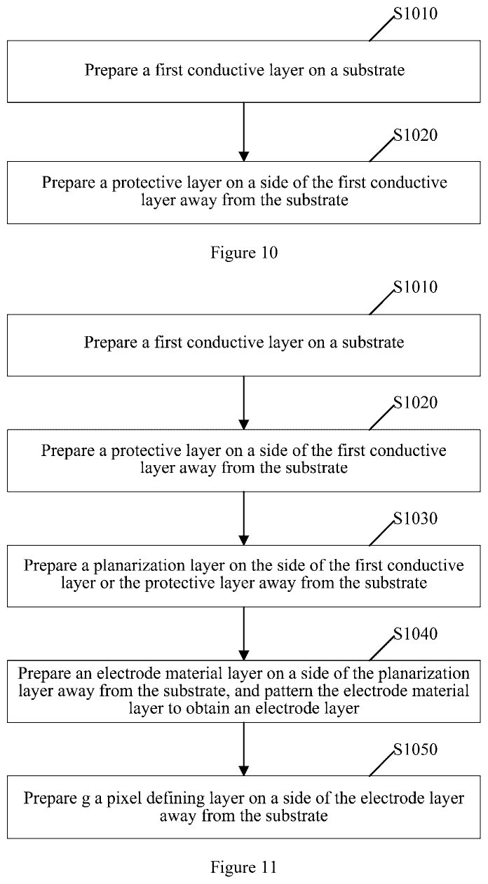

FIG. 10 is a schematic flow chart of a method for preparing a display panel according to an embodiment of the present application. As shown in FIG. 10, the method includes the following steps.

In step S1010, a first conductive layer is prepared on a substrate.

In an embodiment of the present application, the substrate is a flexible substrate. For example, a material of the substrate includes polyimide.

In one embodiment, a first conductive material layer substrate on the substrate, and is patterned to obtain a first conductive layer. The first conductive layer includes a first metal trace located at least in a non-active area.

In one embodiment, before preparing the first conductive layer on the substrate, the method further includes: sequentially preparing at least one second conductive layer on the substrate, the at least one second conductive layer being separated by a second insulating layer; and preparing a first insulating layer on a side of the second conductive layer facing away from the substrate. After the first insulating layer is prepared, the first conductive layer is prepared on a side of the first insulating layer facing away from the substrate.

In step S1020, a protective layer is prepared on a side of the first conductive layer away from the substrate. The protective layer is located in the non-active area and covers at least part of the first metal trace located in the non-active area.

In one embodiment, a protective material layer is deposited on a side of a first electrode layer away from the substrate, and is patterned to obtain the protective layer. By way of example, a mask is used to shield an active area, an inorganic material layer is deposited in the non-active area, and is patterned to obtain the protective layer. Patterning the inorganic material layer includes etching the inorganic material layer (e.g., by dry etching) to obtain the protective layer. In the embodiments of the present application, the region of the non-active area that is covered by the protective layer may be determined as required. For further description, reference is made to FIGS. 3-9 in the embodiments of the present application, which will not be described here again.

FIG. 11 is a schematic flow chart of a method for preparing a display panel according to another embodiment of the present application. The difference between the method shown in FIG. 11 and the method shown in FIG. 10 lies in that the method further includes the following steps.

In step S1030, a planarization layer is prepared on a side of the first conductive layer or the protective layer away from the substrate.

In one embodiment, the planarization layer is prepared by coating the side of the first conductive layer or the protective layer away from the substrate. The planarization layer extends from the active area to the non-active area in which the planarization layer is patterned to form a groove, and the first metal trace at the groove is covered by the protective layer.

In the embodiments of the present application, since the first metal trace at the groove is covered by the protective layer, a developer used during patterning does not reach the surface of the first metal trace, and the first metal trace is prevented from being etched, and the first metal trace still maintains its original form (e.g., as shown in FIG. 1a).

In step S1040, an electrode material layer is prepared on a side of the planarization layer away from the substrate, and is patterned to obtain an electrode layer, i.e., a first electrode layer.

In an embodiment of the present application, the electrode material layer is deposited throughout the side of the planarization layer away from the substrate, and the desired electrode layer is obtained by patterning. The first metal trace at the groove is covered by the protective layer, and the first metal trace in other areas is covered by the planarization layer, and the patterning operation does not cause the first metal trace to be etched, and the first metal trace still maintains its original form (e.g., as shown in FIG. 1a).

In step S1050, a pixel defining layer is prepared on a side of the electrode layer away from the substrate.

The pixel defining layer extends from the active area to the non-active area, and the pixel defining layer in the non-active area covers the protective layer. Since the first metal trace still maintains its original form, no side etching is produced, and the first metal trace is covered by the protective layer and the pixel defining layer, electrochemical corrosion can be avoided during a high-temperature and high-humidity reliability test, to improve the reliability of the display panel.

In an embodiment of the present application, preparing a pixel defining layer on a side of the electrode layer away from the substrate includes: depositing an insulating material layer on the side of the electrode layer away from the substrate, and forming holes in the insulating material layer to facilitate communication of the first metal trace of the first conductive layer and an isolation structure; preparing the isolation structure on a side of the insulating material layer away from the substrate; and patterning the insulating material layer to obtain a pixel defining layer, which encloses pixel openings.

In one embodiment, the method further includes preparing light-emitting units and second electrodes in the pixel openings, and preparing an encapsulation structure on a side of the second electrodes away from the substrate. The light-emitting unit, the second electrode and the encapsulation structure may be prepared by conventional methods, which will not be described in detail in the present application.

In a fifth aspect, an embodiment of the present application provide a display device including the display panel described above, or a display panel prepared by the method described above.

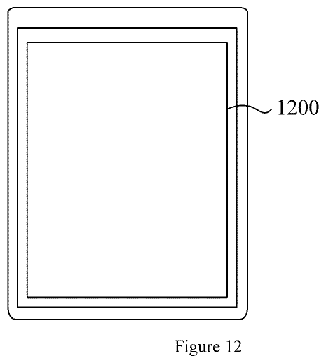

FIG. 12 is a structural schematic view of a display device according to an embodiment of the present application. As shown in FIG. 12, the display device 1200 includes a display panel according to any one of the above embodiments.

The display device 1200 is a product having an image display function. For example, the display device 1200 may be used to display static images, such as pictures or photos. The display device 1200 may also be used to display dynamic images, such as videos.

The display device 1200 may be a laptop computer, a mobile phone, a handheld or portable computer, a camera, a video camera, a vehicle-mounted intelligent central control screen, a calculator, a smart watch, a GPS navigator, an electronic photograph, electronic billboard or signboard, a projector, etc.

In addition, the display device 1200 may also have functions such as photographing, video recording, fingerprint recognition and face recognition. Accordingly, the display device 1200 further includes at least one functional module for implementing the above functions, such as an under-display camera, or an under-display fingerprint recognition sensor.

The basic principle of the present application is described above with respect to particular embodiments, but it should be noted that the benefits, advantages, effects, etc. mentioned in the present application are merely exemplary rather than limiting, and may not be considered as required for each embodiment of the present application. In addition, the specific details disclosed above are only for the purpose of illustration and ease of understanding instead of limitations, and the above details do not limit the present application as implemented by necessarily employing the above specific details.

The block diagrams of devices, apparatuses, equipment, and systems involved in the present application are merely illustrative examples and are not intended to require or imply that they must be connected, arranged, or configured in the manner shown in the block diagrams. The devices, apparatuses, equipment, and systems may be connected, arranged, or configured in any manner. The words such as “including”, “comprising”, “having”, etc. are open words, meaning “including but not limited to”, and can be used interchangeably therewith. The words “or” and “and” used herein refer to the words “and/or” and can be used interchangeably therewith, unless the context clearly indicates otherwise. The word “such as” used herein refers to the phrase “such as but not limited to”, and can be used interchangeably therewith.

It should also be noted that in the apparatus, device and method of the present application, each component or each step can be decomposed and/or recombined. These decompositions and/or recombinations should be regarded as equivalent solutions of the present application.

Various modifications to these aspects will be readily apparent in the art, and the general principles defined herein may be applied to other aspects without departing from the scope of the present application. Therefore, the present application is not intended to be limited to the aspects shown herein, but to be in the broadest scope consistent with the principles and novel features disclosed herein.

The above description has been given for purposes of illustration and description. Moreover, this description is not intended to limit the embodiments of the present application to the form disclosed herein. While various example aspects and embodiments have been discussed above, and it is recognized certain variations, modifications, alterations, additions and sub-combinations thereof.

What is claimed is:

1. A display panel, having an active area and a non-active area at least partially surrounding the active area, the display panel comprising:
a substrate;
an array layer located on one side of the substrate, the array layer comprising a first conductive layer, the first conductive layer comprising a first metal trace, the first metal trace being located at least in the non-active area; and
a protective layer located on a side of the first conductive layer facing away from the substrate and in the non-active area, the protective layer covering at least part of the first metal trace located in the non-active area.

2. The display panel according to claim 1, wherein a cladding of the protective layer on the first metal trace has a thickness greater than or equal to 1000 Å and less than or equal to 5000 Å;
a material of the protective layer comprises at least one of an inorganic material and an organic material;
the first metal trace extends from the non-active area to the active area; and
in a direction perpendicular to the substrate, the first metal trace comprises a first metal layer, a second metal layer and a third metal layer sequentially stacked in a direction away from the substrate, and the protective layer extends from a side surface of the first metal layer to a surface of the third metal layer away from the substrate, and covers at least part of the surface of the third metal layer away from the substrate.

3. The display panel according to claim 1, wherein the non-active area comprises a dam area and a groove area, the groove area being located on a side of the dam area away from the active area; and
the array layer further comprises a planarization layer located on the side of the first conductive layer facing away from the substrate, the planarization layer having a groove in the groove area, the groove exposing part of the first metal trace, and the protective layer at least covering a side surface of the first metal trace exposed at the groove.

4. The display panel according to claim 3, wherein the protective layer at least partially covers the first metal trace and extends in a direction away from the first metal trace until covering the groove; and
the protective layer is provided with a plurality of first openings, an orthographic projection of the plurality of first openings on the substrate being misaligned with an orthographic projection of the first metal trace on the substrate.

5. The display panel according to claim 3, wherein the protective layer covers at least part of the first metal trace in the dam area; and
the dam area comprises at least two dams, and the protective layer at least partially covers the first metal trace located between adjacent dams.

6. The display panel according to claim 5, wherein the protective layer at least partially covers the first metal trace and extends in a direction away from the first metal trace until covering at least part of the dam area;
the protective layer is provided with a plurality of first openings, an orthographic projection of the plurality of first openings on the substrate being misaligned with an orthographic projection of the first metal trace on the substrate; and
the protective layer extends from the groove area to the dam area and covers at least part of the first metal trace in the dam area.

7. The display panel according to claim 3, wherein the non-active area further comprises a first non-active area, the first non-active area being located between the dam area and the active area, and the protective layer covering at least part of the first metal trace in the first non-active area.

8. The display panel according to claim 7, wherein the protective layer at least partially covers the first metal trace and extends in a direction away from the first metal trace until covering at least part of the first non-active area;
the protective layer is provided with a plurality of first openings, an orthographic projection of the plurality of first openings on the substrate being misaligned with an orthographic projection of the first metal trace on the substrate; and
the protective layer extends from the groove area to the first non-active area and covers at least part of the first metal trace in the first non-active area.

9. The display panel according to claim 1, wherein the non-active area comprises a bendable area and a bonding area located on a side of the bendable area away from the active area;
the protective layer at least partially covers the first conductive layer located in the bonding area;
the first conductive layer further comprises a third metal trace located in the bonding area, the first metal trace being electrically connected to the third metal trace; the bonding area comprises a chip bonding area and a flexible printed circuit bonding area, the chip bonding area being provided with a first metal pin, and the flexible printed circuit bonding area being provided with a second metal pin, and the first metal pin and the second metal pin being electrically connected to the third metal trace;
the protective layer covers a side surface of the third metal trace and part of a surface of the third metal trace away from the substrate;
in the chip bonding area, a projection, on the substrate, of the protective layer, that covers the side surface of the third metal trace and part of the surface of the third metal trace away from the substrate, in a cross-sectional direction of the third metal trace has a length greater than or equal to 0.5 μm and less than or equal to 10.5 um; and
in the flexible printed circuit bonding area, the projection, on the substrate, of the protective layer, that covers the side surface of the third metal trace and part of the surface of the third metal trace away from the substrate, in the cross-sectional direction of the third metal trace has a length greater than or equal to 0.5 μm and less than or equal to 14.5 um.

10. The display panel according to claim 9, wherein the protective layer covers the bonding area, and is provided with a plurality of first openings, an orthographic projection of the plurality of first openings on the substrate being misaligned with an orthographic projection of the first conductive layer on the substrate.

11. The display panel according to claim 1, wherein the first conductive layer further comprises a second metal trace, the protective layer further covers at least part of the second metal trace located in the non-active area, and the first metal trace and the second metal trace are located in the same or different metal trace layers; and
the first metal trace comprises a power supply voltage signal line, and the second metal trace comprises at least one of a scan signal line and a data signal line.

12. The display panel according to claim 1, wherein the display panel further comprises a pixel defining layer located on a side of the array layer away from the substrate, the pixel defining layer extending from the active area to the non-active area, and the pixel defining layer in the non-active area being located on a side of the protective layer away from the substrate and at least partially covering the protective layer;
the pixel defining layer in the non-active area is provided with a plurality of second openings, and the protective layer is provided with a plurality of first openings, an orthographic projection of the plurality of second openings on the substrate at least partially overlapping with an orthographic projection of the plurality of first openings on the substrate;
the display panel further comprises an encapsulation structure, the encapsulation structure comprising a first inorganic encapsulation layer, an organic encapsulation layer and a second inorganic encapsulation layer sequentially stacked in a direction facing away from the substrate, the second inorganic encapsulation layer extending from the active area to the non-active area;
the non-active area comprises a dam area, the array layer comprises at least one dam located in the dam area, the pixel defining layer extends from the active area to the dam area and covers at least part of the dam, and the second inorganic encapsulation layer is in contact with the pixel defining layer located on the dam;
the display panel further comprises an isolation structure, the isolation structure comprising a first isolation portion and a second isolation portion sequentially stacked in a direction away from the substrate, an orthographic projection, on the substrate, of a side of the first isolation portion away from the substrate being within an orthographic projection of the second isolation portion on the substrate; and
the isolation structure further comprises a third isolation portion located on a side of the first isolation portion facing the substrate.

13. The display panel according to claim 1, wherein the array layer further comprises a first insulating layer located on a side of the first conductive layer close to the substrate, and the protective layer covers at least part of the first metal trace and extends to cover part of a surface of the first insulating layer.

14. A method for preparing a display panel, the method comprising:
preparing a first conductive layer on a substrate, the first conductive layer comprising a first metal trace located at least in a non-active area; and
preparing a protective layer on a side of the first conductive layer away from the substrate, wherein the protective layer is located in the non-active area and covers at least part of the first metal trace located in the non-active area.

15. The method according to claim 14, wherein preparing a protective layer on a side of the first conductive layer away from the substrate comprises:
depositing a protective material layer on the side of the first conductive layer away from the substrate; and
patterning the protective material layer to obtain the protective layer,
wherein patterning the protective material layer comprises: etching the protective material layer to obtain the protective layer.

16. The method according to claim 15, further comprising:
preparing a planarization layer on the side of the first conductive layer or the protective layer away from the substrate, the planarization layer extending from the active area to the non-active area in which the planarization layer is patterned to form a groove, and the first metal trace at the groove being covered by the protective layer.

17. The method of claim 16, further comprising:
preparing an electrode material layer on a side of the planarization layer away from the substrate, and patterning the electrode material layer to obtain an electrode layer; and
preparing a pixel defining layer on a side of the electrode layer away from the substrate, the pixel defining layer extending from the active area to the non-active area, and the pixel defining layer in the non-active area covering the protective layer.

18. The display panel according to claim 17, wherein preparing a pixel defining layer on a side of the electrode layer away from the substrate comprises: preparing an insulating material layer on the side of the electrode layer away from the substrate, and forming a plurality of holes in the insulating material layer; preparing an isolation structure on a side of the insulating material layer away from the substrate; and patterning the insulating material layer to obtain the pixel defining layer.

19. The method according to claim 14, wherein before preparing the first conductive layer on the substrate, the method further comprises:
sequentially preparing at least one second conductive layer on the substrate, the at least one second conductive layer being separated by a second insulating layer; and
preparing a first insulating layer on a side of the second conductive layer facing away from the substrate.

20. A display device, comprising:
a display panel, having an active area and a non-active area at least partially surrounding the active area, the display panel comprising:
a substrate;
an array layer located on one side of the substrate, the array layer comprising a first conductive layer, the first conductive layer comprising a first metal trace, the first metal trace being located at least in the non-active area; and
a protective layer located on a side of the first conductive layer facing away from the substrate and in the non-active area, the protective layer covering at least part of the first metal trace located in the non-active area.
